(19) United States
(12) Patent Application Publication
(10) Pub. No.: US 2019/0320546 A1
(43) Pub. Date: Oct. 17, 2019

(54) CASING FOR A RACK SERVER AND METHOD

(71) Applicant: FUJITSU LIMITED, Kawasaki-shi (JP)

(72) Inventor: Friedrich Köhler, München (DE)

(73) Assignee: FUJITSU LIMITED, Kawasaki-shi (JP)

(21) Appl. No.: 16/297,939

(22) Filed: Mar. 11, 2019

(30) Foreign Application Priority Data
Apr. 12, 2018 (DE) 102018108703.9

(51) Int. Cl. H05K 7/14; H05K 5/02

(52) U.S. Cl. CPC H05K 7/1488; H05K 5/02; H05K 7/1401

(57) ABSTRACT

The invention relates to a casing for a rack server, which comprises a chassis with a chassis base and a surface to be equipped and a reinforcement bridge. In the mounted state, the chassis base and the reinforcement bridge are slightly bent. The bent reinforcement bridge is fastened to the bent chassis base. The bending or curvature of the chassis base and of the reinforcement bridge is convexly shaped with respect to the surface to be equipped.

The invention relates to a casing for a rack server, which comprises a chassis with a chassis base and a surface to be equipped, and to a method for reinforcing a rack server casing.

In a complete system expansion, rack servers are subject to a higher weight load through processors, main memory, slot cards, fans, etc. The high weight load is problematic, as the casing trough can deform under the weight load. A deforming of the casing trough leads to a hanging chassis base, which can quickly exceed the permitted installation space in the rack. The exceeding of the permitted installation space can have an adverse impact on the components in the plugin located below. This problem is particularly significant for 1-HE server casings (1 height unit server casings) in the 19 unit rack installation, as the casing is, as a rule, conditionally bendable due to the small installation height.

In order to pursue a solution to these problems, the server was heretofore riveted with additional sheet-metal parts, in order to reinforce it. Subsequently the chassis base is pre-bent, through embossing, in multiple processing steps. The pre-bent chassis base is meant to act against the bending forces in a high weight load. Disadvantageous in this methodology is the cost-driving, complex embossing. The additional working steps increase the price of the casing. In addition, the embossing leaves visible embossing edges on the base of the casing. These embossment edges allow the chassis to be seen as deformed or buckled, which can lead to customer complaints.

It is therefore the object of the invention to provide a casing for a rack server, which casing at least partially counteracts the bending forces in the equipped casing, but is simultaneously cost-effective and cosmetically acceptable.

This object is achieved through the features of the patent claims 1 and 12. Advantageous configurations of the invention are specified in the dependent claims.

The invention is characterized by a casing for a rack server, which casing comprises a chassis with a chassis base and a surface to be equipped and a reinforcement bridge, e.g. in the form of a fan bridge. The chassis base and the reinforcement bridge are slightly bent in the mounted state. The bending or curvature of the chassis base and of the reinforcement bridge is convexly shaped, in the mounted state, with respect to the surface to be equipped.

This convex shape of the chassis base and of the reinforcement bridge in a non-equipped casing or a not completely-equipped casing counteracts the bending force of a fully-equipped chassis base. The upwardly-bent chassis base, in the installed state, causes the fully-equipped or partially-equipped chassis base not to dip. For a downward dipping of the chassis base, the chassis base would have to deform (e.g. in an s-shape) such that the chassis base overcomes the horizontal plane between the upward deflection and a downward deflection. In a normal equipping, these types of heavy forces for a deforming of the chassis base do not arise, so that a dipping of the chassis base is reliably prevented.

In an advantageous configuration of the casing according to the invention, the chassis base comprises at least two embossments or elevations on the surface to be equipped. In the following, the term “embossment” is used, which also includes the term “elevation”. At the same time, the reinforcement bridge comprises at least two corresponding openings, which are formed in such a way that an embossment can fit through an opening. The pre-specified reinforcement bridge is arranged on the pre-bent chassis base in such a way that the embossments are respectively arranged in an opening. The embossments can protrude over the opening.

The embossments are preferably spaced in such a way that the smallest distance between two embossments in the non-bent state of the chassis base is smaller than the smallest distance between the openings. The distance between the embossments is measured from a side surface of a first embossment to a side surface of a second embossment, wherein the two side surfaces are preferably facing one another. The distance between the openings is measured from an inner surface of a first opening to an inner surface of a second opening. The smallest distance between the openings is referred to as distance dimension “X”. Consequently, the smallest distance between the embossments in the non-bent state of the chassis base is smaller than “X” and is named distance dimension “X−α”, with α>0.

The smallest distance between the embossments in the non-bent state, namely the distance dimension “X−α”, is thus smaller than the smallest distance between the openings, namely the distance dimension “X”. How much smaller the distance dimension “X−α” is than the “X” depends upon the extent to which the chassis base and the reinforcement bridge, in the mounted state, are to be bent, namely the degree of curvature. If the chassis base is to be only slightly bent (that is, should only have a small curvature, and withstand lower bending forces), then α₁ is relatively small in the distance dimension “X−α₁”. If the chassis base is to be more strongly bend than in the first scenario (thus should comprise aa greater curvature and should withstand stronger bending forces), then α₂ is relatively large in the distance dimension “X−α₂”, namely greater than α₁.

The distance between the embossments in the bent chassis base preferably corresponds roughly to the distance between the openings in the reinforcement bridge, namely the distance dimension “X”. The embossments of the chassis base can thus be guided through the respective openings of the reinforcement bridge. The embossments, together with the reinforcement bridge, serve as spacers, and hold the chassis base in the bent and pre-clamped state. When loaded, the embossments can thusly receive the bending forces. The side surfaces, facing each other, of the embossments respectively serve as abutment surfaces for an opening. These abutment surfaces of the embossments respectively press against an inner surface of the respective opening, which is termed abutment inner surface. The abutment inner surface of a first opening lies nearest to the abutment inner surface of a second opening. The distance between the abutment inner surface of the first opening and the abutment inner surface of a second opening is the above-mentioned distance dimension “X”. The distance between the abutment surface of the first embossment and the abutment surface of the second embossment is, in a non-bent chassis base, the above-mentioned distance dimension “X−α”.

Preferably, the bent chassis base and the bent reinforcement bridge are connected with one another or are fastened to one another by means of rivets. The chassis base is clamped onto a riveting device in a bent state, such that the distance between the embossments is enlarged to the distance dimension “X”. The embossments in the chassis base can thusly be guided through the openings in the reinforcement bridge, which are distanced from one another with the distance dimension “X”. To that end, the reinforcement bridge is initially, on the chassis base, clamped bent on the riveting device, so that each embossment is guided through an opening. The bent chassis base and the bent reinforcement bridge lie nearly form-fittingly on one another. In this clamped state, the chassis base and the reinforcement bridge are riveted to one another.

The reinforcement bridge preferably comprises a rectangular profile. The rectangular profile supports the stability or the rigidity of the reinforcement bridge. The reinforcement bridge can additionally be provided with recesses in order to enable the bending.

The embossments are preferably of a cuboid design, and the openings are correspondingly of quadrangular design. The embossments can also be formed as truncated pyramid. This form of the embossments can make the guiding of the embossments through the openings or adjustment during the assembly easier, as the inclined surface of the truncated pyramid can serve as a guide surface. The openings are preferably formed larger than the largest cross-section of the embossments.

The housing is preferably designed for a 1-HE rack server plugin.

Advantages of the housing according to the invention and the method according to the invention are that costly method steps like embossing steps are omitted. Without the embossing, no visible embossing edges, as in previous solution attempts, are present as well, which presence can otherwise lead to customer complaints. Additionally, a defined pre-clamping and bending of the chassis base is possible through the pre-defined distance dimension. The method according to the invention further includes stable production processes, which lead to a uniform quality.

Advantageous configurations of the inventions are subsequently explained in more detail based on the schematic drawings.

The drawings show in:

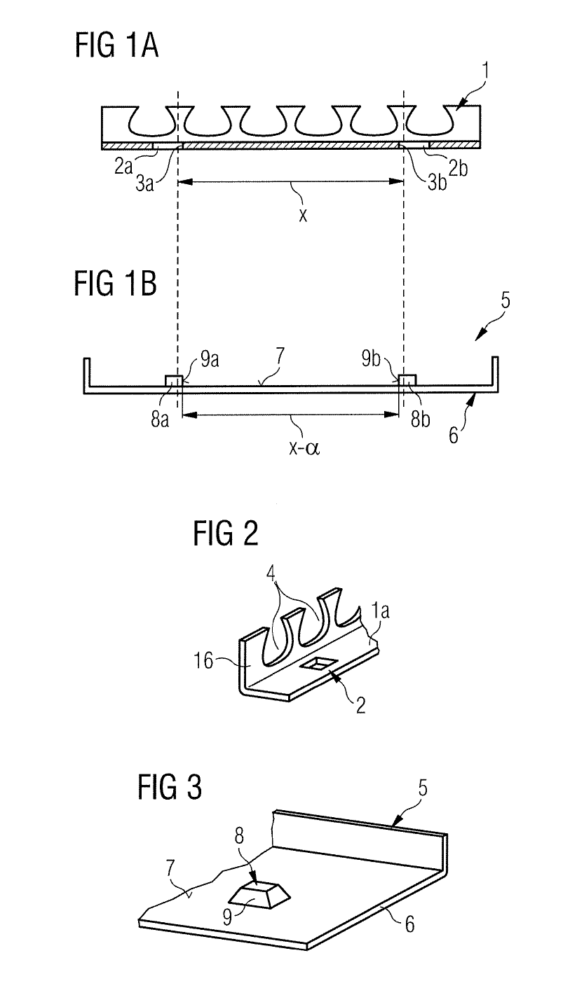

FIG. 1A a cross-section of a reinforcement bridge of a casing according to the invention with a rectangular profile,

FIG. 1B a cross-section of a chassis base of a casing according to the invention, which base fits with the reinforcement bridge depicted in FIG. 1A,

FIG. 2 a perspective section of a reinforcement bridge of a casing according to the invention with an opening,

FIG. 3 a perspective section of a chassis base of a casing according to the invention with an embossment,

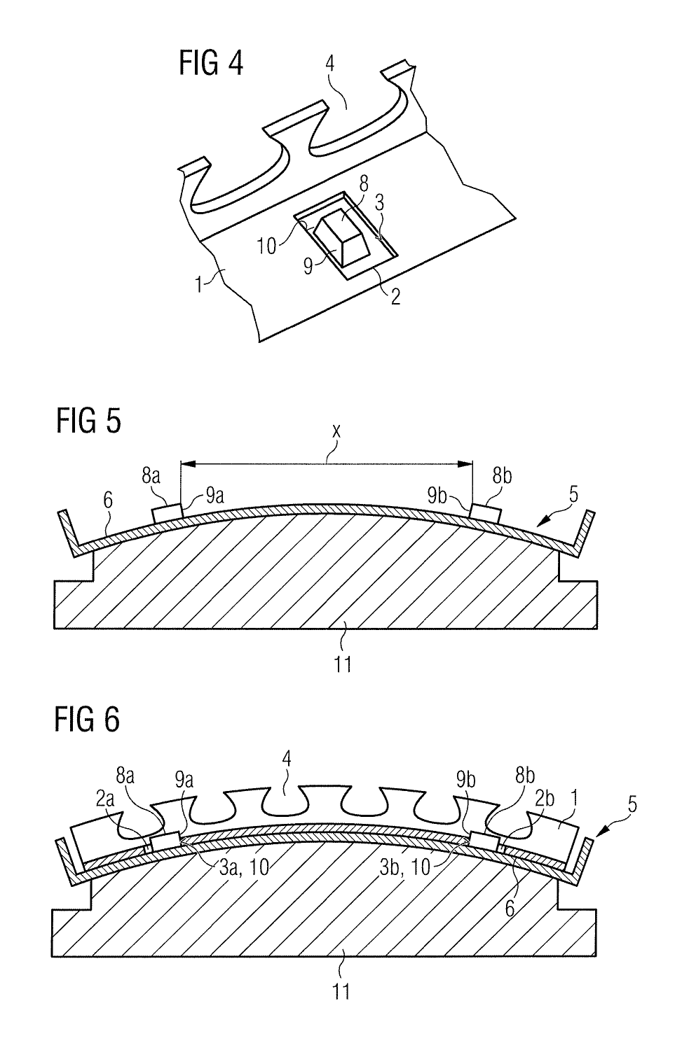

FIG. 4 a perspective section of a reinforcement bridge and a chassis base, according to the invention, in the fastened state.

FIG. 5 a cross-section of a riveting device, on which the chassis base is clamped in a bent state, and

FIG. 6 a cross section of a riveting device, on which a chassis base and a reinforcement bridge are respectively clamped in a bent state.

FIG. 1A and FIG. 2 show an exemplary embodiment of a reinforcement bridge 1 in the form of a fan bridge according to the invention. The reinforcement bridge 1 shows two openings 2, 2a, 2b, which are arranged in the defined distance (distance dimension “X”) from each other. The openings 2, 2a, 2b are of a quadrangular design and each opening 2, 2a, 2b comprises four inner surfaces 3, 3a, 3b. The distance dimension X is measured from a first inner surface 3a of a first opening 2a to an second inner surface 3b of a second opening 2b, wherein the distance between the first inner surface 3a and the second inner surface 3b represents the smallest distance between the openings 2a, 2b. In other words, the first inner surface 3a and the second inner surface 3b lie the closest to one another. Put another way, the first inner surface 3a and the second inner surface 3b are directed towards the middle of the reinforcement bridge 1.

The reinforcement bridge 1 comprises a rectangular profile (see FIG. 2). The rectangular form of the profile contributes to forming the reinforcement bridge more stably and rigidly. A first reinforcement bridge part 1a is arranged at a right-angle to a second reinforcement bridge part 1b, in order to form an L-shaped profile or an L-shaped cross-section through the longitudinal axis. The first reinforcement bridge part 1a is provided with the two openings 2, 2a, 2b. The second reinforcement bridge part 1b is provided with multiple recesses 4. The recesses 4 are, for example, formed in the form of a circular segment. The recesses 4 make the bending of the reinforcement bridge 1 easier.

FIG. 1B shows a trough-like chassis 5 with a chassis base 6, the dimensions of which conform to the reinforcement bridge 1 represented in FIG. 1A. The chassis 5 comprises a surface 7 to be equipped with components on the inner side of the chassis base 6. Two embossments 8a, 8b are arranged on the surface 7 to be equipped. The embossments 8a, 8b can be designed to be integral with the chassis base 6 or the chassis 5 or can be fastened to the chassis base 6.

The distance between the embossments 8a, 8b is represented as “X−α” in FIG. 1B, with α>0. For example, the embossments 8, 8a, 8b are of cuboid design and respectively comprise four side surfaces. One of these side surfaces is referred to as an abutment surface 9, 9a, 9b (see FIGS. 1B and 3). The two embossments 8, 8a, 8b are distanced from one another, in a non-bent state, by the distance dimension “X−α”. This distance is measured from a first abutment surface 9a of a first embossment 8a to a second abutment surface 9b of a second embossment 8b, wherein the first abutment surface 9a and the second abutment surface 9b are facing each other.

The embossments 8, 8a, 8b can alternatively be formed as a truncated pyramid (see FIG. 3). An advantage of the truncated-pyramid-shaped embossments 8 is that the form offers a sliding or adjusting effect when the embossments 8 are guided through the respective openings 2 (see FIGS. 3 and 4).

FIG. 4 shows a section of a chassis base 6 and a section of a reinforcement bridge 1, in which an embossment 8 is already guided through an opening 2. The abutment surface 9 of the embossment 8 abuts on a corresponding inner surface 3 of the opening 2. In a weight loading of the chassis base 6, the abutment surfaces 9 of the embossments 8 press against one of the inner surfaces 3, 3a, 3b of the respective opening 2, which surface is named abutment inner surface 10. (The first inner surface 3a and the second inner surface 3b from the FIG. 1A also serve as abutment inner surfaces 10.) The embossments 8 thusly hold the reinforcement bridge 1 in the bent and pre-clamped state and prevent a downward deflection of the chassis base in weight loading. The abutment surface 9 abuts, for example, form-fittingly or nearly form-fittingly on the affected abutment inner surface 10, 3a, 3b.

FIG. 5 shows a chassis 5, in the clamped and bent state, on a riveting device 11. The chassis base 6, which is represented in FIG. 1B, is clamped to the riveting device 11. The chassis base 6 is bent and clamped on the riveting device 11, so that the distance between the embossments 8a, 8b, in the non-bent state of the chassis base 6, namely distance dimension “X−α” (see FIG. 1B), is enlarged until the distance between the embossments 8a, 8b, in the bent state of the chassis base 6, has reached distance dimension “X”. In other words, the chassis base 6 is bent and stretched, and the two embossments 8a, 8b are thereby spread open so that the distance between a part of the first abutment surface 9a of the first embossment 8a and a part of the second abutment surface 9b of the second embossment 8b are enlarged to “X”.

Through the expansion of the distance between the embossments 8a, 8b to the distance dimension “X”, a correspondingly bent reinforcement bridge 1 (as represented in FIG. 1A) can be nearly form-fittingly placed upon the chassis base 6, and the embossments 8a, 8b can be guided through the respective openings 2a, 2b (see FIG. 6).

The chassis base 6 and the reinforcement bridge 1 are both, in FIG. 6, represented in a defined clamped state. In this defined clamped state, the chassis base 6 and the reinforcement bridge 1 are riveted, or the embossments 8a, 8b of the chassis base 6 hold in the openings of the reinforcement bridge 1 through a form-fit. The chassis base 6 and/or the reinforcement bridge 1 are conveniently manufactured from sheet metal.

### LIST OF REFERENCE CHARACTERS

1 reinforcement bridge, e.g. in the form of a fan bridge
2 opening
3 inner surface of an opening
4 recess of the reinforcement bridge
5 chassis
6 chassis base
7 surface to be equipped, of the chassis base
8 embossment
9 abutment surface of an embossment
10 abutment inner surface of an opening
11 riveting device

1. A casing for a rack server, comprising:
a chassis with a chassis base and a surface to be equipped, and
a reinforcement bridge,
wherein the chassis base and the reinforcement bridge are respectively bent,
the bent reinforcement bridge is fastened to the bent chassis base, and
the bending of the chassis base and of the reinforcement bridge is convexly shaped with respect to the surface to be equipped.

2. The casing according to claim 1,
wherein
the chassis base comprises at least two embossments on the surface to be equipped and the reinforcement bridge comprises at least two corresponding openings, which are shaped in such a way that one embossment can fit through one opening.

3. The casing according to claim 2,
wherein
the smallest distance between the embossments in the non-bent state of the chassis base is smaller than the smallest distance between the openings,
wherein the distance between the embossments is measured from a first side surface of a first embossment to a second side surface of a second embossment,
wherein the distance between the openings is measured from a first inner surface of a first opening to a second inner surface of a second opening.

4. The casing according to claim 3,
wherein
the distance between the embossments in the bent chassis base (6) approximately corresponds to the distance between the openings.

5. The casing according to claim 1,
wherein
the bent chassis base and the bent reinforcement bridge are connected to one another by means of rivets.

6. The casing according to claim 1, wherein
the reinforcement bridge comprises a rectangular profile.

7. The casing according to claim 2,
wherein
the embossments are of cuboid design and the openings correspondingly are of quadrangular design.

8. The casing according to claim 2,
wherein
the embossments are formed as a truncated pyramid and the openings correspondingly are of quadrangular design.

9. The casing according to claim 2, wherein
the side surfaces of the embossments facing one another serve as abutment surfaces for the openings.

10. The casing according to claim 1, wherein
the rack server is formed as a rack server plugin.

11. The casing according to claim 10,
wherein
the rack server plugin measures 1 height unit (1-HE).

12. A method of reinforcing a rack server casing, in which a reinforcement bridge is connected to a chassis of the rack server casing,
wherein the chassis comprises a chassis base with a surface to be equipped, on which at least two embossments are arranged, and
the reinforcement bridge comprises at least two corresponding openings, which are shaped in such a way that one embossment can fit through one opening,
wherein the smallest distance between the openings from an inner surface of a first opening to an inner surface of a second opening is referred to as distance dimension “X”, and the smallest distance between the embossments from the side surface to the side surface in the non-bent state of the chassis base is smaller than “X”,
wherein the method comprises the following method steps:
(a) the chassis base is clamped on to a riveting device in a bent state, such that the distance between the embossments becomes “X”,
(b) the reinforcement bridge, on the chassis base, is clamped on to the riveting device in a bent state, such that the embossments are respectively guided through an opening, and
(c) the chassis base and the reinforcement bridge are riveted to one another in the clamped state.

13. The method according to claim 12,
characterized in that
in method step, the reinforcement bridge rests on the chassis base in a largely form-fitting manner.

14. The method according to claim 12,
wherein
the embossments each comprise an abutment surface facing the other embossment, and in method step the abutment surface of each embossment buts against an abutment inner surface of an opening.
